(19) United States
(12) Patent Application Publication
(10) Pub. No.: US 2009/0151776 A1
(43) Pub. Date: Jun. 18, 2009

(54) Solar cell module and process for the production thereof

(75) Inventor: Ulrich Schindler, Bayern (DE)

Correspondence Address: HOFFMANN & BARON, LLP, 6900 JERICHO TURNPIKE, SYOSSET, NY, 11791, US

(73) Assignee: LEONHARD KURZ Stiftung & Co. KG

(21) Appl. No.: 12/316,108

(22) Filed: Dec. 9, 2008

(30) Foreign Application Priority Data
Dec. 13, 2007 (DE) 102007060108.7-33

(51) Int. Cl. H01L 31/048; H01L 31/042; H01L 21/28

(52) U.S. Cl. 136/251; 136/244; 438/73; 257/E21.158

(57) ABSTRACT

The invention concerns a solar cell module which has a layer-form translucent carrier substrate and at least two solar cells arranged on the carrier substrate and including at least one organic solar cell, wherein at least one upper solar cell is arranged on a top side of the carrier substrate and at least one lower solar cell is arranged on an underside of the carrier substrate, and a process for the production of such a solar cell module.

### BACKGROUND OF THE INVENTION

The invention concerns a solar cell module which has a layer-form translucent carrier substrate and at least two solar cells arranged on the carrier substrate and including at least one organic solar cell, and a process for the production of such a solar cell module.

Organic solar cells or organic components and processes for the production thereof are known. The term organic component is generally used to denote such a component having at least one functional layer which is at least partially based on an organic material. A functional layer is in particular an electrically conducting layer, a semiconductor layer, an electrically insulating layer or a substrate. All kinds of organic, metallorganic and/or inorganic plastic materials are referred to as organic materials, in which respect there is no limitation to a carbonaceous material. Rather silicones, polymers or oligomers as well as what are referred to as ‘small molecules’ are also embraced thereby.

DE 103 26 547 A1 describes an organic solar cell on a layer-form translucent carrier substrate which is constructed in the form of a tandem solar cell or photovoltaic multicell, also referred to as a multijunction cell. In that case two solar cell elements are optically and electrically connected in series, the solar cell elements having a common electrode which is between a photovoltaically active layer of the one solar cell element and a photovoltaically active layer of the solar cell element adjacent thereto.

U.S. Pat. No. 2005/0272263 A1 describes the production of a solar cell module having a plurality of organic solar cells which are arranged in a roll-to-roll process in mutually juxtaposed relationship on one side of a common carrier substrate and which are only electrically connected in series.

At the present time organic solar cells have levels of efficiency of about between 3 and 5% which are far below the levels of efficiency already achieved with silicon-based solar cells. The efficiency of solar cell modules having individual organic solar cells electrically connected together is even much less by virtue of the geometrical filling factor (GFF) and the electrical losses which occur.

### SUMMARY OF THE INVENTION

Now the object of the invention is to provide a solar cell module of improved efficiency—containing organic solar cells—and to provide a process for the production thereof.

The object is attained for a solar cell module which has a layer-form translucent carrier substrate and at least two solar cells arranged on the carrier substrate and including at least one organic solar cell, in that at least one upper solar cell is arranged on a top side of the carrier substrate and at least one lower solar cell is arranged on an underside of the carrier substrate.

In that respect the terms ‘top side’ and ‘underside’ are only used to conceptually distinguish mutually opposite sides of the carrier substrate but not to define a spatial position of those sides. Thus the underside of the carrier substrate can face upwardly, downwardly or to the side and the top side of the carrier substrate can face upwardly, downwardly or to the side, and so forth.

Because of the double-sided utilisation of the translucent carrier substrate the solar cell module according to the invention permits integration of a higher number and in particular an at least double number of solar cells, with the same carrier substrate area. The efficiency of the solar cell module can thus be markedly increased, with the carrier substrate area remaining the same.

In particular it has proven to be worthwhile if the at least one upper solar cell and/or the at least one lower solar cell is an organic solar cell.

It is equally possible for the solar cell module to have at least one inorganic solar cell in combination with the at least one organic solar cell. Thus the at least one upper solar cell can be an organic solar cell and the at least one lower solar cell can be an inorganic solar cell, or both organic and also inorganic solar cells can be arranged on the top side and/or the underside.

In that respect it has proven worthwhile if the at least one upper solar cell and the at least one lower solar cell are arranged in at least region-wise overlapping relationship viewed perpendicularly to the plane of the carrier substrate or are arranged in coincident relationship one behind the other. That is advantageous in particular when it is possible by the process engineering involved to implement a small spacing between adjacent solar cells on the top side and the underside of the carrier substrate.

Likewise however it is also possible for the at least one upper solar cell and the at least one lower solar cell to be arranged in mutually juxtaposed relationship, in particularly alternately, when viewed perpendicularly to the plane of the carrier substrate. That is advantageous in particular if it is not possible with the process engineering involved to implement a small spacing between adjacent solar cells on one side of the carrier substrate. That can be the case for example if production of an organic solar cell with sharp contours is not possible by virtue of running of applied functional layer material for building up the solar cell.

Preferably the solar cell module is translucent and in particular transparent. A transparent solar cell module permits the arrangement of such a module in the region of displays, windowpanes, security documents with printed information and so forth, in which case it is possible for information to be read out through the solar cell module. The incidence of light on such a solar cell module can be in the region of the upper and/or lower solar cells.

The solar cell module however can also be opaque, for example if a layer arranged on the side of the solar cell module, remote from the incidence of light, is opaque.

Preferably the at least one upper solar cell and the at least one lower solar cell respectively have at least one photovoltaically active, in particular organic, semiconductor layer in a layer thickness in the range of between 50 and 300 nm, in particular in the range of between 100 and 250 nm. Such thin photovoltaically active semiconductor layers are translucent, in particular transparent.

The photovoltaically active semiconductor layers of organic solar cells are preferably organic and have in particular semiconducting polymers, in contrast for example to dye solar cells or Gratzel cells which are constructed on the basis of photoactive dyes so that different operative principles are involved.

It has proven worthwhile if at least two electrically interconnected upper solar cells are arranged on the top side of the carrier substrate. In that case the upper solar cells can be connected in series or in parallel or some of the upper solar cells can be connected in series and some of them in parallel. The upper solar cells can be connected for example as in above-mentioned U.S. Pat. No. 2005/0272263 A1.

It has further proven worthwhile if the at least two upper solar cells are arranged stacked one upon the other when viewed parallel to the plane of the carrier substrate and/or are arranged in mutually juxtaposed relationship. This can accordingly involve an arrangement in which photovoltaic multijunction cells as are shown for example in above-mentioned DE 103 26 547 A1 are arranged on the top side of the carrier substrate.

It is also preferable if at least two electrically interconnected lower solar cells are arranged on the underside of the carrier substrate. The lower solar cells in that case can be connected in series, connected in parallel or some of the lower solar cells can be connected in series and some in parallel. Connection of the lower solar cells can be effected for example as in above-mentioned U.S. Pat. No. 2005/0272263 A1.

In that case, preferably also the at least two lower solar cells are arranged stacked one upon the other when viewed parallel to the plane of the carrier substrate and/or are arranged in mutually juxtaposed relationship. Accordingly this can also involve an arrangement in which photovoltaic multijunction cells, for example as shown in above-mentioned DE 103 26 547 A1, are arranged on the underside of the carrier substrate.

Electrical connection of upper and lower solar cells is also possible, in which case the carrier substrate is provided with a through opening, what is referred to as a via, which is filled with an electrically conducting material which forms an electrically conducting connection between an electrode layer of the at least one upper solar cell and an electrode layer of the at least one lower solar cell. That can also be effected by sewing together electrode layers on the underside and the top side of the carrier substrate with an electrically conductive thread or another procedure.

In particular individual solar cells and/or multijunction cells are arranged on the top side and/or the underside of the carrier substrate, being in particular electrically connected together.

Depending on the respective side from which light is incident on the solar cell module in that case generally at least the solar cell or cells facing towards the incidence of light must be translucent so that the solar cell arranged thereafter as viewed in the direction of the incidence of light and in particular also the last solar cell is also still supplied with light. If for example the incidence of light is on the side of the upper solar cell or cells and the at least one upper solar cell and the at least one lower solar cell are arranged in coincident relationship one behind the other, when viewed perpendicularly to the plane of the carrier substrate, the at least one upper solar cell is thus to be translucent. If the incidence of light is for example on the part of the upper solar cell or cells and the at least one upper solar cell is in the form of at least one upper multifunction cell, wherein as viewed perpendicularly to the plane of the carrier substrate the at least one upper multifunction cell and the at least one lower solar cell are arranged in coincident relationship one behind the other, the upper multifunction cell is to be translucent. If the incidence of light is for example in respect of the lower solar cell or cells and if the at least one upper solar cell is in the form of at least one upper multifunction cell, wherein as viewed perpendicularly to the plane of the carrier substrate the at least one upper multifunction cell and the at least one lower solar cell are arranged in coincident relationship one behind the other, then the lower solar cell and at least the solar cells of the upper multifunction cell which as viewed in the direction of the incidence of light cover a further solar cell are to be translucent, and so forth.

It has proven worthwhile if the at least one upper solar cell and the at least one lower solar cell respectively have at least one photovoltaically active, in particular organic semiconductor layer whose spectral sensitivity is different. In particular it has also proven worthwhile if at least two upper solar cells and/or at least two lower solar cells respectively have at least one photovoltaically active, in particular organic semiconductor layer whose spectral sensitivity is different. Thus the light spectrum which is available or still available at the respective solar cell, in particular in the case of solar cells optically connected in series, can be utilised in more specifically targeted fashion.

In addition it has proven worthwhile if the at least one upper solar cell and the at least one lower solar cell when viewed perpendicularly to the plane of the carrier substrate are of a different surface extent.

In that respect the at least one upper and the at least one lower solar cell when viewed perpendicularly to the plane of the carrier substrate can further differ in their contour and/or width. That affords a further option in terms of design configuration, with the same solar cell structure. A different width for the solar cells can be provided for example in order to adapt solar cells having different photovoltaically active semiconductor layers in respect of their electrical values, such as for example in respect of internal resistance. A strip-shaped configuration for the at least one upper and/or the at least one lower solar cell is preferred. In that case the longitudinal direction of the strip-shaped at least one upper solar cell can be oriented parallel or perpendicular to the longitudinal direction of the strip-shaped at least one lower solar cell, or can be oriented at any desired angle. A mirror-image arrangement of upper and lower solar cells has also proven worthwhile, with the carrier substrate forming the plane of the mirror.

The translucent carrier substrate is preferably formed from glass or plastic material, in particular PET, PEN or PVC. In that respect the carrier substrate is translucent at least in the regions in which light must be able to pass through the carrier substrate to a solar cell. It is further preferred if the carrier substrate is of a layer thickness in the range of between 6 μm and 1 mm, in particular in the range of between 12 μm and 150 μm. The use of flexible or bendable carrier substrates is particularly advantageous, for example in the form of plastic films or laminates which can be quickly and inexpensively processed in a roll-to-roll process. Preferably the carrier substrate is not only translucent but also transparent or clear. It is however also possible to use a semitransparent translucent carrier substrate.

A further advantageous configuration provides that the carrier substrate is non-flat and/or has an uneven top side and/or underside in region-wise manner or over its full area. In that way the carrier substrate has a larger surface area than a flat or undeformed carrier substrate so that a larger effective area is available for energy production. The carrier substrate can be so designed that the upper and lower cells are not arranged parallel but at a given angle to each other, by the solar cells following the top side and the underside of the carrier substrate, wherein the top side and the underside, as viewed in cross-section of the carrier substrate, are oriented—at least locally—not parallel but angled relative to each other.

It can further be provided that the carrier substrate has a coloration. The coloration can for example perform decorative purposes, it can be used for example for the artistic design of window surfaces, or it can be provided for light filtering purposes.

The carrier substrate can be made from different materials which behave differently, for example which under the effect of temperature expand to differing degrees or shrink unidirectionally or bidirectionally, which involve different transmissivity for the incident light, which exhibit a color reaction under incident light, and so forth.

Furthermore the carrier substrate can have electrical components or devices such as a liquid crystal layer, an antenna, or an IC chip, for example for constructing an RFID tag.

Preferably the at least one upper solar cell and the at least one lower solar cell respectively have at least one translucent, in particular transparent, electrically conducting first electrode layer, at least one photovoltaically active, in particular organic semiconductor layer and at least one translucent, in particular transparent, electrically conducting second electrode layer, wherein the at least one photovoltaically active semiconductor layer is arranged between the at least one first electrode layer and the at least one second electrode layer. In the case of an organic solar cell the at least one photovoltaically active semiconductor layer is preferably an organic semiconductor layer.

The following structure for an upper and/or lower solar cell has proven particularly advantageous. In that case, in this sequence, starting from the carrier substrate, the solar cell has at least the one second electrode layer, at least the one photovoltaically active, in particular organic semiconductor layer and the at least one first electrode layer. There can be further layers such as the functional or blocker layers referred to hereinafter.

The at least one upper solar cell and/or the at least one lower solar cell further has in particular at least one translucent, in particular transparent functional layer which increases the efficiency of the respective and/or the respectively other solar cell.

A solar cell module and/or a solar cell has in that respect in particular at least one translucent, in particular transparent, organic functional layer which increases the efficiency of the solar cell and which has light-scattering and/or luminescent particles which are arranged when viewed perpendicularly to the at least one semiconductor layer in overlapping relationship with and/or beside same.

When an organic functional layer with light-scattering particles is used, they scatter and/or deflect the incident light. In that case the light is diverted into one or more directions so that the light, in particular in the at least one photovoltaically active, in particular organic semiconductor layer of the solar cell, covers a longer distance than would be the case without the particles. In that respect the light beams which have already been diverted possibly impinge on further particles which again scatter the light so that escape of the light or parts of the light out of the at least one photovoltaically active semiconductor layer can in the best-case scenario be completely prevented. Light-scattering particles which when viewed perpendicularly to the at least one photovoltaically active semiconductor layer are arranged beside same or not in overlapping relationship therewith serve to divert the light which would have missed the photovoltaically active semiconductor layer and would have remain unused, in the direction of the photovoltaically active semiconductor layer of the solar cell. The light which is incident on and/or beside the solar cell is thus better utilised and thereby increases the efficiency of the solar cell.

If an organic functional layer with luminescent particles is used, they are excited by incident light of at least one wavelength and emit light of another wavelength. The luminescent particles are in that case so selected that the emitted wavelength can be better used or at least used by the photovoltaically active semiconductor layer of the solar cell.

In that case the light exciting the luminescent particles can be in particular light of a wavelength which cannot be put to use or which can be only poorly put to use by the photovoltaically active semiconductor layer of the solar cell. The light emitted by the luminescent particles is uniformly irradiated at all sides and can thus be used independently of direction. The light incident on and/or beside the solar cell is thus put to better use and thereby increases the efficiency of the solar cell.

The luminescent particles used can be fluorescent particles or phosphorescent particles, in which respect it is also possible to use a combination thereof.

Alternatively or in combination therewith a solar cell module and/or a solar cell has in particular at least one translucent, in particular transparent, organic or inorganic functional layer which increases the efficiency of the solar cell and which is arranged on one side of the solar cell module which faces towards the incident light and has a refractive index between the refractive index of air and the refractive index of the immediately adjoining layer of the solar cell module.

If such an organic or inorganic functional layer is used on the light incidence side of the solar cell module that provides that reflection of the light upon impinging on the solar cell module is reduced. More light passes into the solar cells by way of the interface between air and the solar cell module, than without that measure. Light which was formerly reflected at the interface and which was deflected unused by the solar cell module is now available for the major part for energy production, with the efficiency of the solar cell module being increased by up to 20%.

Preferably those organic or inorganic functional layers which have a defined refractive index are respectively produced in a layer thickness in the range of between 15 and 300 nm. Particularly suitable materials for forming functional layers are dielectric materials which are translucent, in particular transparent, in such a layer thickness, such as SiO₂, ZnS, Al₂O₃, ZrO₂, MgF₂, Ca₂O₃ and so forth.

Alternatively to or in combination with a functional layer containing light-scattering and/or luminescent particles and/or a functional layer with a defined refractive index the solar cell module and/or a solar cell in particular has at least one translucent, in particular transparent, organic or inorganic functional layer which increases the efficiency of the solar cell and which has at least one relief structure which reduces reflection of light incident in the solar cell at that functional layer in comparison with reflection at such a functional layer with a flat interface, in particular by at least 20%. Such an organic or inorganic functional layer provides that more light passes by way of the interface between air and the solar cell module, than without that measure. Light which was formerly reflected at the interface and which was deflected without being used by the solar cell module is now available for the major part for energy production, with the efficiency of the solar cell being increased by up to 20%.

In that respect it has proven desirable if the at least one relief structure is in the form of a matt structure. Matt structures, on a microscopic scale, have fine relief structure elements which determine the scatter capability and which can only be described with statistical characteristic values such as for example a mean roughness value Ra, a correlation length Ic and so forth, wherein the values for the mean roughness value Ra lie in the range of between 20 nm and 2000 nm, with preferred values in the range of between 50 nm and 1000 nm, while the correlation length Ic in at least one direction involves values in the range of between 200 nm and 50,000 nm, preferably in the range of between 500 nm and 10,000 nm.

It has further proven advantageous if the at least one relief structure is in the form of a periodic structure, in particular in the form of a blaze grating, a line structure, a cross grating, a linear or crossed sine grating, a circular grating, a lens structure or a combination of two or more of those structures.

It is particularly preferred if the at least one relief structure has a depth-to-width ratio of >0.3 and in particular >1 as generally an improved function, that is to say reduced reflection, is achieved thereby.

Here the term depth is used to denote the spacing between the highest and the lowest mutually following points of such a relief structure, that is to say this involves the spacing between the ‘peak’ and the ‘trough’. The term width denotes the spacing between two adjacent highest points, that is to say between two ‘peaks’. Now, the greater the depth-to-width ratio, the correspondingly steeper are the ‘peak sides’. For example, the relief structure can involve periodic relief structures or quasi-periodic relief structures with discretely distributed line-shaped regions which are only in the form of a ‘trough’, with the spacing between two ‘troughs’ being a multiple greater than the depth of the ‘troughs’. In that case the calculated depth-to-width ratio of quasi-periodic relief structures can be approximately zero so that, in the case of discretely arranged relief structures which are formed substantially only from one ‘trough’, the depth of the ‘trough’ is to be related to the width of the ‘trough’ to determine the depth-to-width ratio.

It has proven desirable if the at least one periodic relief structure involves a spatial frequency in the range of between 300 and 4000 lines/mm.

In that respect, to form a translucent, in particular transparent organic functional layer, preferably printing media are used, which have at least one organic binding agent and to which light-scattering and/or luminescent particles are added or into which the relief structures are embossed.

Organic or inorganic functional layers whose refractive indices have to be definedly set are selected in dependence on the refractive index of the materials used for forming same, wherein in particular up to three functional layers can be used in mutually stacked relationship. Inorganic functional layers with a refractive index which is between that of air and the layer of the solar cell module, that is towards the light incidence side, are formed in particular from magnesium fluoride or SiO₂.

Organic materials for forming organic functional layers are preferably dissolved in an organic solvent or solvent mixture, a printing medium is produced, and it is preferably applied by printing using intaglio printing. Alternatively it is also possible to use flexoprinting, screen printing or a nozzle for the structured application of the printing medium.

The at least one upper and the at least one lower solar cell are preferably made up of the same materials, but can also be formed from different materials. Thus the materials for forming the first electrode layers and/or the second electrode layers and/or the photovoltaically active semiconductor layers can differ. With a plurality of upper solar cells and/or a plurality of lower solar cells, the materials for forming the first electrode layers and/or the second electrode layers and/or the photovoltaically active semiconductor layers on the top side and/or on the underside of the carrier substrate can differ, wherein there can be upper and/or lower solar cells of different materials, possibly also of a differing structure or involving different electrical circuitry.

It has proven worthwhile if the at least one photovoltaically active semiconductor layer is an organic semiconductor layer formed by at least two organic semiconductor materials, insofar as a composite is formed from at least one electron donor and at least one electron acceptor, in particular in a ratio of between 2:0.5 and 0.5:2, preferably in a ratio of between 1:0.9 and 1:1. Preferably the at least one electron donor is formed from a polythiophene, in particular poly(3-hexylthiophene) (P3HT) or MDMO-PPV [poly(1-methoxy-5-(3-,7-dimethyloctyloxy)-1,4-phenylene vinylene] and the at least one electron acceptor is formed from fullerenes such as C₆₀ or a fullerene derivative, in particular PCBM ([6,6]-phenyl-C₆₁-butyric acid methyl ester).

Furthermore the photovoltaically active semiconductor layer may also be made up of two mutually superposed, in particular organic sublayers which however must be in the form of very thin sublayers to reduce unwanted recombinations of the charge carriers and not unnecessarily increase the resistance in the direction of the surface normal. If the organic sublayers are very thin then the short-circuit strength of a photovoltaically active semiconductor layer made up from organic sublayers can be lower than that of a photovoltaically active semiconductor layer of about 100 nm thickness of organic composite material.

In the case of the photovoltaically active semiconductor layer formed from two mutually superposed sublayers, it is to be provided that, in respect of mutually inverted photovoltaic cells, the orientation of the photovoltaically active semiconductor layers is inverted, that is to say the layer sequence of the two sublayers is inverted and thus also alternated. The photovoltaically active semiconductor layer formed from two sublayers is a polarised functional layer and the photovoltaically active semiconductor layer formed from composite material is an unpolarised functional layer of the solar cell or a layer which is also referred to as a ‘bulk heterojunction’. The photovoltaically active semiconductor layer may also involve a matrix structure.

An electrode layer for constructing a solar cell can be formed from a metal, in particular gold, silver, copper, aluminum, nickel or alloys of at least two of those metals and in that case, depending on the layer thickness, can be opaque or translucent, in particular semitransparent or transparent. An electrode layer comprising a material with inherent color such as for example gold is in that case in particular of a relatively small layer thickness or in the form of a grating structure to be sufficiently translucent. In that case a grating structure is referred to here as semitransparent as it has both opaque and also transparent regions but it appears predominantly transparent. It has further proven desirable if a translucent electrode layer is formed from indium tin oxide (ITO) or IMI (ITO metal ITO). That is usually deposited by cathode sputtering. It is however also possible to use doped polyethylene, polyaniline, organic semiconductors, nanoparticulate solutions and so forth for forming an electrode layer. Organic electrode layers can be applied particularly easily by a printing process so that organic electrode layers are preferred over metallic electrode layers.

It is possible to arrange between an electrode layer and the at least one photovoltaically active semiconductor layer of a solar cell, at least one hole blocker layer, in particular of TiOₓ, of a layer thickness in the range of between 10 and 50 nm, which improves electrical dissipation of charges. Sometimes a layer which performs the function of an electron blocker layer is arranged on the side of the photovoltaically active semiconductor layer, that is towards the at least one hole blocker layer. In that respect electrically conductive polymer, in particular poly-3,4-ethylene dioxythiophene (PEDOT) has proven advantageous. Preferably the electron blocker layer is formed from PEDOT/PSS (poly(3,4-ethylene dioxythiophene)poly(styrene sulfonate)), of a layer thickness in the range of between 50 and 150 nm.

Because the nature of the blocker layers can determine the polarity of a solar cell it has proven advantageous if the same material is used to form the first and second electrode layers. In that case it can advantageously be provided that the electrically conducting connections between two solar cells are also formed from the material of the electrode layers, thereby affording a particularly simple structure for the solar cell module according to the invention.

The two blocker layers can form a unit with the electrode layers and/or at the same time perform further functions in a solar cell, for example as a wetting aid and/or as a barrier. If the first electrode layer is formed for example from ITO then for example a PEDOT/PSS layer can be arranged between the first electrode layer and the photovoltaically active semiconductor layer. The PEDOT/PSS layer forms the electron blocker layer and further improves wetting of the electrode layer with the photovoltaically active semiconductor layer as the surface tension of the dried PEDOT/PSS layer, for example in the region of 40 mN/m, is very much greater than that of an applied solution for forming a photovoltaically active semiconductor layer. If the second electrode layer for example is in the form of a vapor-deposited silver layer then a PEDOT/PSS layer applied to the photovoltaically active semiconductor layer can act as a barrier for the silver atoms which impinge in the vapor deposition procedure and can reduce the probability of short-circuits and/or incorrect contacts in the solar cell.

It is preferred for both blocker layers to be formed with the same layer thickness. However, implementation with different layer thicknesses is also possible to provide for adaptation to the functionality of the respectively adjoining photovoltaically active semiconductor layer.

The first electrode layer is formed for example from a transparent indium tin oxide layer (ITO) of a layer thickness in the range of between 40 and 150 nm or an ITO metal ITO composite (IMI) of a total layer thickness of 40 nm. The second electrode layer is formed for example from a semitransparent or transparent metallic layer, preferably Ag or Au, involving a layer thickness in the range of between 70 and 120 nm, or Cr and Au involving a total layer thickness in the range of between 70 and 120 nm, wherein the Cr layer serves as a bonding agent and is of a layer thickness of for example about 3 nm. ITO forms an anode when the electron blocker layer is applied to the ITO layer. If the hole blocker layer is applied to the ITO layer then the ITO layer forms a cathode.

It is particularly preferred if a solar cell has at least one functional layer having at least one diffractive and/or refractive further relief structure which, viewed perpendicularly to the plane of the at least one photovoltaically active semiconductor layer, is arranged in overlapping relationship with and/or beside same. By virtue of the further relief structure it is possible for light to be deflected in a specifically targeted fashion in the direction of the at least one photovoltaically active semiconductor layer or into regions thereof, to focus the light or to reflect it, so that the result is a further increase in the efficiency of the solar cell. The further relief structure however can also serve only decorative purposes in order for example to produce an optically variable element such as a hologram or Kinegram®. A combination of light-deflecting further relief structures and further relief structures serving for decorative purposes is also possible.

It has proven particularly desirable if the at least one further relief structure is in the form of a matt structure, an asymmetrical relief structure, a linear or crossed linear grating, a diffractive or refractive lens structure or a combination of at least two of such structures. Relief structures of that kind are particularly well suited to scattering light impinging thereon, collecting it, focusing it or deflecting it. Functional layers with two relief structures can be respectively translucent or opaque depending on the arrangement involved having regard to the incidence of light into the solar cell. Thus for example an opaque reflecting functional layer can be arranged with at least one further relief structure on the side of the solar cell module that is remote from the light incidence side.

To protect the solar cell module from mechanical or chemical influences, it has proven worthwhile if the at least one upper solar cell and/or the at least one lower solar cell has a translucent and in particular transparent encapsulation layer on its side remote from the carrier substrate. The encapsulation layer serves to shield the functional layers of the solar cell from harmful environmental influences and is preferably formed from an inorganically coated polymer film, the coating being based in particular on tantalum, SiOₓ or SiOₓ/Na.

In accordance with a process of the invention the solar cell module according to the invention is formed by the at least one upper, in particular organic solar cell and the at least one lower, in particular organic solar cell being printed on the carrier substrate. That can be effected quickly and inexpensively.

In accordance with a further process of the invention the solar cell module according to the invention can be formed by at least the at least one photovoltaically active, in particular organic semiconductor layer of the at least one upper solar cell and the at least one lower solar cell being printed. Certain functional layers of the solar cells such as for example the electrode layers are then produced for example by sputtering or vapor deposition, but can also be applied by printing depending on the respective material.

In particular the at least one upper, in particular organic solar cell and the at least one lower, in particular organic solar cell are formed in a roll-to-roll process on a flexible carrier substrate, in particular a plastic film. The use of a carrier substrate comprising a flexible plastic film makes it possible to form bendable solar cell modules as the functional layers of the solar cells are usually of a very much smaller layer thickness than the carrier substrate and do not impair or do not substantially impair the flexibility thereof. The functional layers of a solar cell can be readily applied to such a carrier substrate in a continuous process, being the at least one photovoltaically active semiconductor layer and/or the blocker layers, in particular in a printing process. That provides for successive applications of functional layer materials, wherein each of the functional layers to be formed can be structured according to the demands involved, that is to say can be of a patterned configuration. In the roll-to-roll process structured functional layers can be applied by printing in accurate register relationship, possibly in a plurality of printing operations. By way of example intaglio printing, ink jet printing or screen printing can be provided as the printing process. It is however also possible to use other application technologies such as spin application, sputtering or vapor deposition and so forth.

It can also be provided that a functional layer is firstly applied over the full surface area and is then structured, for example by etching, a lift-off process, an embossing process, laser ablation and so forth.

It is further possible for at least one of the functional layers of the solar cells to be applied by a laminating process. It is possible for example to provide different laminating films which can be combined in different ways and which thus permit a highly inexpensive solution with an end product of high quality, in particular for small-scale series.

In that case the carrier substrate is used in particular in the form of an elongate flexible film strip which can be transported from one roll to another so that a plurality of solar cells can be formed thereon. In that case the elongate film strip is provided wound on a supply roll, pulled off same, thereupon the individual functional layers of the solar cells are successively formed and finally the film strips including a plurality of solar cells which are formed thereon and which are possibly electrically connected to each other are wound on to a further supply roll. Subsequently it is possible to individually separate solar cells and/or solar cell groups, in particular by cutting or stamping, connection or further process steps, such as for example a thermal, chemical or mechanical treatment, a coating operation, irradiation and so forth.

If an electrically insulating separating layer is provided between adjacent solar cells that can be applied for example by screen printing. In that case it fills up the intermediate spaces between the solar cells, with the contours of the separating layer being determined by the edge contours of the solar cells. There is therefore no need to take steps for application in accurate register relationship.

Preferably the procedure firstly involves forming the at least one upper solar cell on the top side of the carrier substrate, and then forming the at least one lower solar cell on the underside of the carrier substrate. In that case the at least one upper solar cell is formed completely before the at least one lower solar cell is formed.

It is however equally possible for the formation of the at least one upper solar cell on the top side of the carrier substrate and the formation of the at least one lower solar cell on the underside of the carrier substrate to be effected at the same time. That is advantageous in particular if the upper and lower solar cells are arranged in coincident relationship and the functional layers for constructing the solar cells are preferably of identical dimensions, and preferably also of identical composition.

The formation of identical functional layers of the upper and lower solar cells on the carrier substrate is preferably carried out in a run through the machine, by the carrier substrate being guided by way of a turning device. It is however also possible to use special printing and application procedures for that purpose.

It has proven desirable if the top side and/or the underside of the carrier substrate is provided with at least one position marking and positioning of the at least one lower or at least one upper solar cell is effected in accurate positional relationship with the at least one upper or lower solar cell by means of alignment of the at least one lower or upper solar cell at the at least one position marking.

The at least one position marking is preferably printed on the carrier substrate. It is however also possible to provide for local deformation of the carrier substrate, for example by embossing, or local coloration of the carrier substrate, for example by means of laser irradiation, for forming a position marking.

It is preferred if the solar cell module is in the form of a laminating film which can be laminated on to articles or if the solar cell module is in the form of a film which can be backed by injection in an in mold process, in which case three-dimensional injection molded articles are produced.

The solar cell module according to the invention can therefore also be used as a semimanufactured article to produce end products which, besides their actual primary purpose of use, can further be used for environmentally friendly production of energy. It is possible for example to equip vehicle bodies, weather balloons and traffic control devices with solar cell modules.

### BRIEF DESCRIPTION OF THE DRAWINGS

FIGS. 1a through 2 are intended to describe a solar cell module according to the invention and the production thereof by way of example and in cross-section. In the Figures:

FIG. 1a shows the formation of a first electrode layer on a carrier substrate,

FIG. 1b shows the formation of a hole blocker layer on the first electrode layer,

FIG. 1c shows the formation of a photovoltaically active semiconductor layer on the hole blocker layer,

FIG. 1d shows the formation of an electron blocker layer on the photovoltaically active semiconductor layer,

FIG. 1e shows the formation of an electrically insulating layer,

FIG. 1f shows a first solar cell module,

FIG. 1g shows a second solar cell module, and

FIG. 2 shows a third solar cell module.

### DETAILED DESCRIPTION OF THE PREFERRED EMBODIMENTS

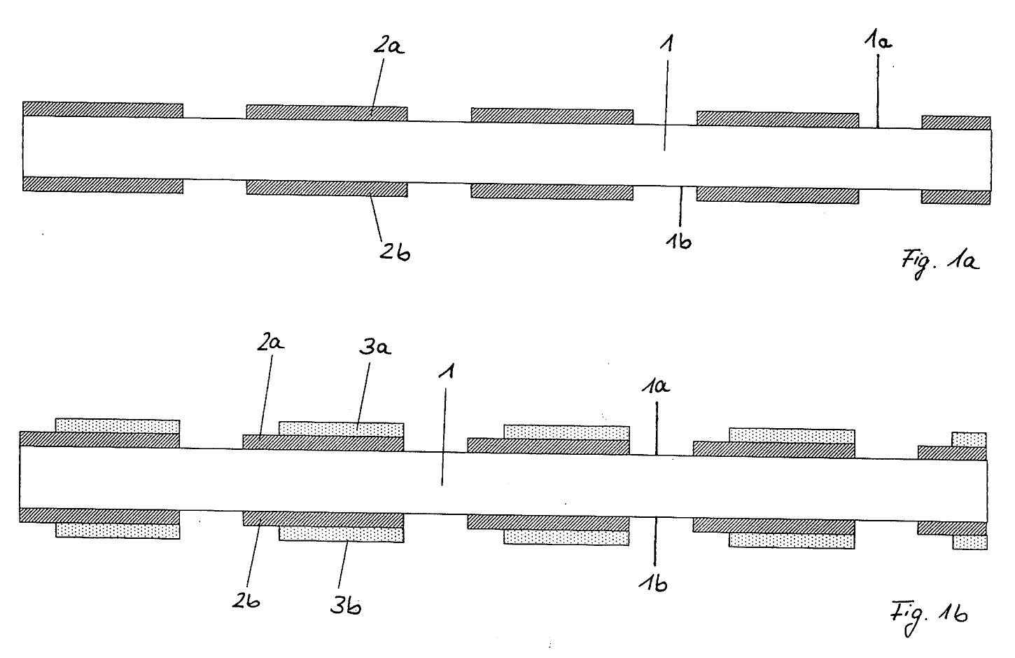

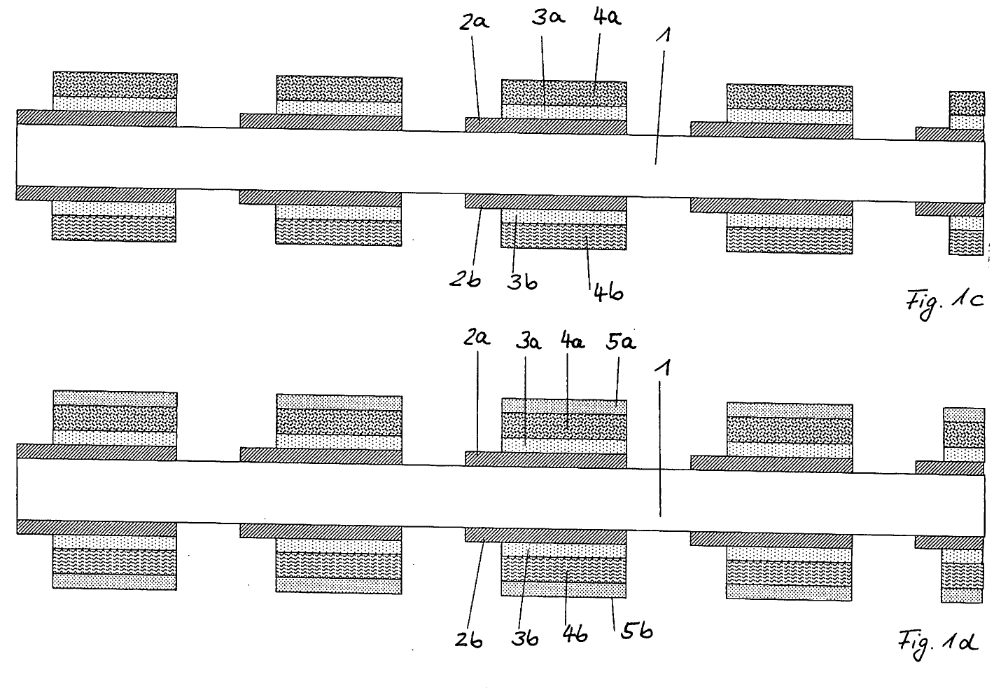

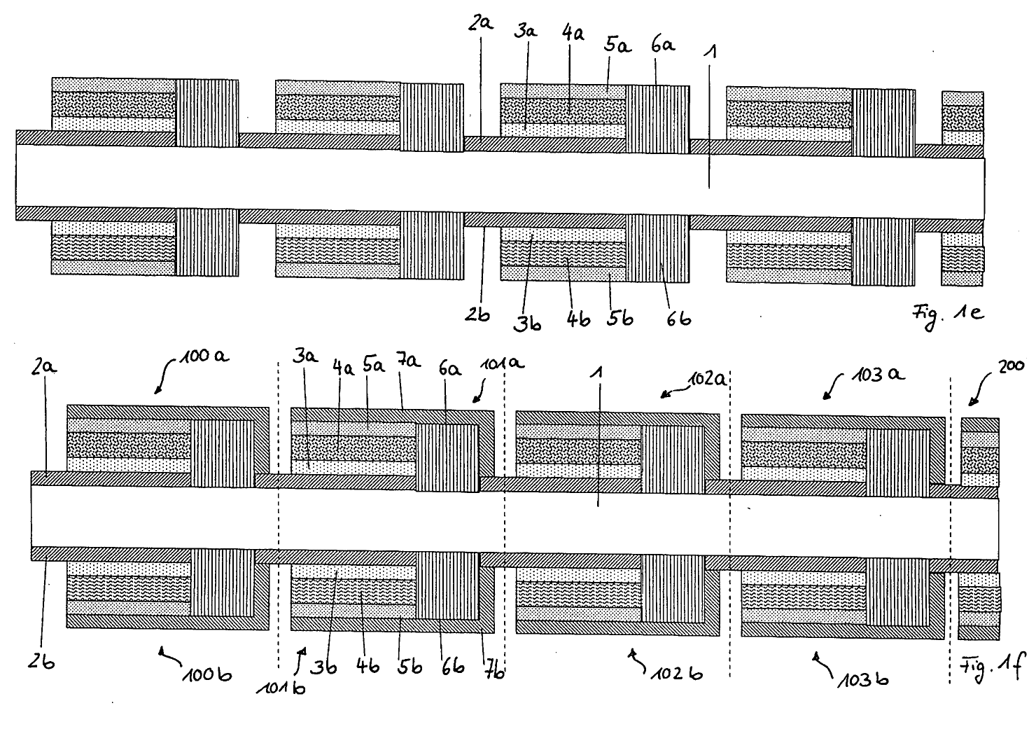

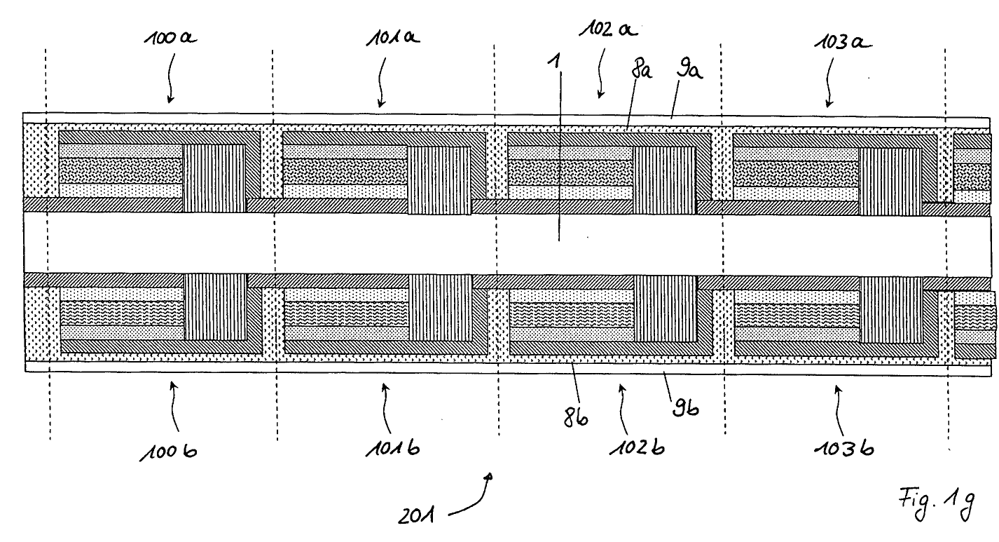

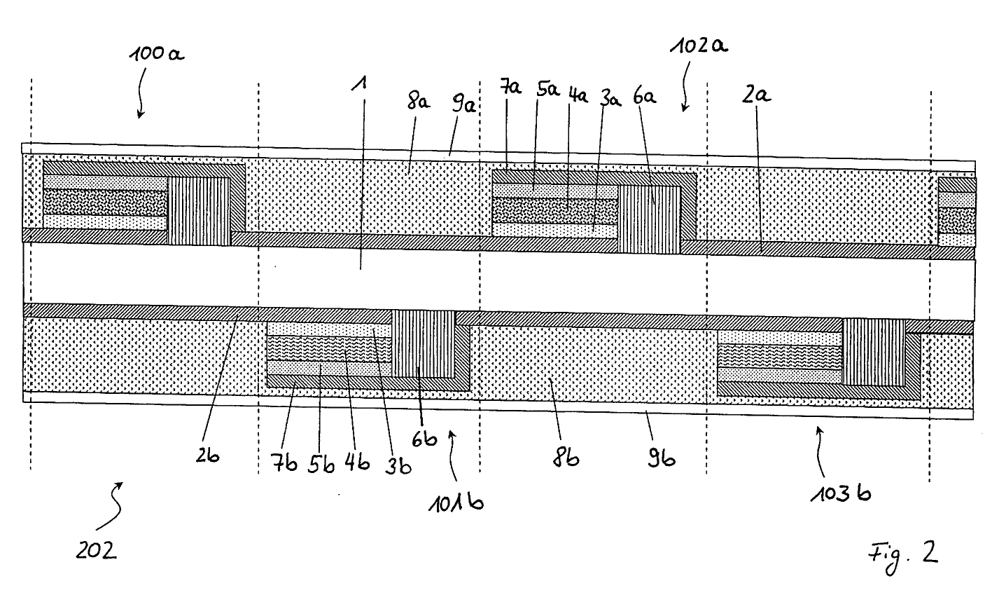

FIG. 1a shows a view in cross-section of a translucent transparent carrier substrate 1 of PET of a thickness of 23 μm. Formed on the top side 1a of the carrier substrate 1 are mutually juxtaposed upper solar cells 100a, 101a, 102a, 103a electrically connected in series (see FIG. 1g), by successively forming one functional layer after another for the upper solar cells 100a, 101a, 102a, 103a. Mutually juxtaposed solar cells 100b, 101b, 102b, 103b electrically connected in series (see FIG. 1g) are constructed on the underside 1b of the carrier substrate 1 by successively forming one functional layer after another for the lower solar cells 100b, 101b, 102b, 103b. In that respect, a first electrode layer, a hole blocker layer, an organic photovoltaically active semiconductor layer comprising electron donors and electron acceptors, an electron blocker layer and a second electrode layer are formed as functional layers of each solar cell. In addition, there are further functional layers in the form of electrically insulating layers, adhesive layers and encapsulation layers. To form the upper solar cells 100a, 101a, 102a, 103a on the top side 1a of the carrier substrate 1, firstly a patterned transparent upper first electrode layer 2a of IMI is produced by sputtering with a total layer thickness of 60 nm. In that respect the upper first electrode layer 2a can be deposited in pattern form on the carrier substrate 1 by way of a mask or alternatively thereto it can be applied over the full surface area and then partially removed, for example by means of laser ablation or etching.

To form the lower solar cells 100b, 101b, 102b, 103b on the underside 1b of the carrier substrate 1, a patterned transparent lower first electrode layer 2b is formed from IMI by sputtering with a total layer thickness of 60 nm. In that respect the lower first electrode layer 2b can be deposited on the carrier substrate 1 in pattern form by way of a mask or alternatively thereto it can be applied over the full surface area involved and then partially removed, for example by means of laser ablation or etching.

The upper and/or lower first electrode layer 2a, 2b can also be in the form of an organic functional layer which is formed by patterned printing of a solution containing organic electrically conducting material and subsequent drying. The upper and also the lower first electrode layers 2a, 2b are here to be semitransparent or transparent.

The process steps for forming the upper first electrode layer 2a and for forming the lower first electrode layer 2b on the carrier substrate 1 can be effected either at the same time or in succession.

FIG. 1b shows a view in cross-section illustrating the layer structure of FIG. 1a, wherein the formation of a patterned upper hole blocker layer 3a on the upper first electrode layer 2a and the formation of a patterned lower hole blocker layer 3b on the lower first electrode layer 2b are effected simultaneously or in succession. The hole blocker layers 3a and 3b are made from TiOₓ in a layer thickness of 30 nm. The hole blocker layers 3a, 3b are formed either by sputtering or by deposit out of a solution.

FIG. 1c shows a view in cross-section illustrating the layer structure of FIG. 1b, wherein the formation of a patterned upper organic photovoltaically active semiconductor layer 4a on the upper hole blocker layer 3a and the formation of a patterned lower organic photovoltaically active semiconductor layer 4b on the lower hole blocker layer 3b are effected simultaneously or in succession. The upper organic photovoltaically active semiconductor layer 4a is formed from a composite material which contains P3HT (poly(3-hexylthiophene)) and PC₇₀BM ([6,6]-phenyl-C₇₁ butyric acid methyl ester) in a ratio of 1:1.2.

The lower organic photovoltaically active semiconductor layer 4b is formed from a composite material which contains PCPDTBT (poly[2,6-(4,4-bis(2-ethylhexyl)-4H-cyclopenta[2,1-b; 3,4-b′]dithiophene)-alt-4,7-(2,1,3-benzothiadiazole)]) and PCBM ([6,6]-phenyl-C₆₁ butyric acid methyl ester) in a ratio of 0.8:1.1.

Both photovoltaically active semiconductor layers 4a, 4b are formed by intaglio printing, wherein a respective solution containing the corresponding composite material is applied by printing and then dried. It is also possible to use other processes for forming the semiconductor layer or layers which manage without solutions, such as for example sublimation processes.

Alternatively it is also possible to use other materials, material composites and material concentrations for forming the photovoltaically active semiconductor layer or layers. In addition the photovoltaically active semiconductor layer or layers of the upper and lower solar cell or cells may have the same or different layer thicknesses.

FIG. 1d shows a view in cross-section illustrating the layer structure of FIG. 1c, wherein the formation of an upper electron blocker layer 5a on the upper photovoltaically active semiconductor layer 4a and the formation of a lower electron blocker layer 5b on the lower photovoltaically active semiconductor layer 4b are effected simultaneously or in succession. The electron blocker layers 5a, 5b are formed from PEDOT/PSS in a layer thickness of 70 nm. The electron blocker layers 5a, 5b are formed by patterned printing of a solution containing PEDOT/PSS and subsequent drying.

FIG. 1e shows a view in cross-section illustrating the layer structure of FIG. 1d, wherein the formation of an upper electrically insulating layer 6a on the top side 1a of the carrier substrate 1 and the formation of a lower electrically insulating layer 6b on the underside 1b of the carrier substrate 1 are effected simultaneously or in succession, the electrically insulating layers 6a, 6b being formed from a lacquer based on acrylates and PVC. In that case the upper electrically insulating layer 6a is so arranged that it covers the regions of the top side 1a of the carrier substrate 1, that are free from the upper first electrode layer 2a. The lower electrically insulating layer 6b is so arranged that it covers the regions of the underside 1b of the carrier substrate 1, that are free from the lower first electrode layer 2b. The layer thickness of the upper and lower electrically conducting layers 6a, 6b is so selected that the side, remote from the carrier substrate 1, of the respectively adjoining upper and lower electron blocker layers 5a, 5b forms one plane with the side, remote from the carrier substrate, of the upper and lower electrically conducting layers 6a, 6b respectively.

FIG. 1f shows a view in cross-section illustrating the first solar cell module 200 which is formed by a procedure whereby the layer structure of FIG. 1a is supplemented by a patterned translucent transparent upper second electrode layer 7a and a patterned translucent transparent lower second electrode layer 7b, by means of screen printing of a silver paste. Alternatively one of the second electrode layers 7a, 7b can be opaque. The layer structure of FIG. 1e is simultaneously or successively completed with the upper second electrode layer 7a on the top side 1a of the carrier substrate 1 and the lower second electrode layer 7b on the underside 1b of the carrier substrate 1, wherein the upper second electrode layer 7a forms an electrically conducting connection to the respectively adjacently arranged upper first electrode layer 2a and the lower second electrode layer 7b forms an electrically conducting connection to the respectively adjacently arranged lower first electrode layer 2b. The solar cell module 200 thus has the upper solar cells 100a, 101a, 102a, 103a on the top side 1a of the carrier substrate 1 and the lower solar cells 100b, 101b, 102b, 103b on the underside 1b of the carrier substrate 1. In that respect the upper solar cells 100a, 101a, 102a, 103a are connected in series by means of the upper second electrode layer 7a and the lower solar cells 100b, 101b, 102b, 103b are connected in series by means of the lower second electrode layer 7b.

FIG. 1g shows a view in cross-section illustrating a second solar cell module 201 with a layer structure as shown in FIG. 1f. In addition a translucent transparent upper adhesive layer 8a comprising an acrylate mixture and an upper encapsulation layer 9a of translucent transparent PET are applied, which cover the upper solar cells 100a, 101a, 102a, 103a and protect them from harmful environmental influences. In addition a translucent transparent lower adhesive layer 8b of an acrylate mixture and a lower encapsulation layer 9b comprising translucent transparent PET are applied, which cover the lower solar cells 100b, 101b, 102b, 103b and protect them from harmful environmental influences. The encapsulation layers 9a, 9b, on their side remote from the carrier substrate 1, are each vapor-deposited with a transparent functional layer of SiOₓ which is not shown separately here and which has a defined refractive index between that of air and that of the encapsulation layer 9a, 9b. The SiOₓ functional layer reduces the reflection of the incident light at the interface between the solar cell module 201 and the adjoining air and improves the transmission of light incident on the solar cell module 201 into the solar cell module so that more light reaches the photovoltaically active semiconductor layers 4a, 4b and the efficiency of the solar cells 100a, 101a, 102a, 103a, 100b, 101b, 102b, 103b is improved.

FIG. 2 shows a third solar cell module 202 in which the upper solar cells 100a, 102a are arranged on the top side of the carrier substrate 1 and the lower solar cells 101b, 103b are arranged on the underside of the carrier substrate 1. The layers of the solar cell module correspond to those shown in FIGS. 1a through 1g. The arrangement of the series-connected upper solar cells 100a, 102a and the series-connected lower solar cells 101b, 103b is selected to alternate, wherein as viewed perpendicularly to the plane of the carrier substrate 1 the upper solar cells 100a, 102a are disposed beside the lower solar cells 101b, 103b without overlapping.

The process steps for forming the upper solar cells 100a, 101a, 102a, 103a and for forming the lower solar cells 100b, 101b, 102b, 103b on the carrier substrate 1 can be effected either simultaneously or in succession. Thus the functional layers of the upper solar cells 100a, 101a, 102a, 103a can be formed alternately with functional layers of the lower solar cells 100b, 101b, 102b, 103b. It is however also possible firstly to completely form the upper solar cells 100a, 101a, 102a, 103a and then to add the lower solar cells 100b, 101b, 102b, 103b, or vice-versa. Each of the possible procedures has its own advantages which can predominate depending on the overall concept.

For simplification purposes, FIGS. 1f, 1g and 2 do not show electrically conducting connections which are usually further provided, for example relating to the circuitry of the solar cells, for taking off the electric current produced when there is incident light, and so forth.

It will be apparent to the man skilled in the art that, using very different solar cells with or without functional layers containing light-scattering and/or luminescent particles and/or involving defined refractive indices or at least one relief structure and possibly also further relief structures, it is possible in a simple fashion to form a very wide range of variations in and combinations of individual cells and/or multicells for constructing a solar cell module.

1. A solar cell module which has a layer-form translucent carrier substrate and at least two solar cells arranged on the carrier substrate and including at least one organic solar cell, wherein
at least one upper solar cell is arranged on a top side of the carrier substrate and at least one lower solar cell is arranged on an underside of the carrier substrate.

2. A solar cell module as set forth in claim 1, wherein the at least one upper solar cell and/or the at least one lower solar cell is an organic solar cell.

3. A solar cell module as set forth in claim 1, wherein the at least one upper solar cell and the at least one lower solar cell are arranged in at least region-wise overlapping relationship viewed perpendicularly to the plane of the carrier substrate or are arranged in coincident relationship one behind the other.

4. A solar cell module as set forth in claim 1, wherein the at least one upper solar cell and the at least one lower solar cell are arranged in mutually juxtaposed relationship when viewed perpendicularly to the plane of the carrier substrate.

5. A solar cell module as set forth in claim 1, wherein the at least one upper solar cell and the at least one lower solar cell respectively have at least one photovoltaically active semiconductor layer in a layer thickness in the range of between 50 and 300 nm.

6. A solar cell module as set forth in claim 1, wherein at least two electrically interconnected upper solar cells are arranged on the top side of the carrier substrate.

7. A solar cell module as set forth in claim 6, wherein the at least two upper solar cells are arranged stacked one upon the other when viewed parallel to the plane of the carrier substrate and/or are arranged in mutually juxtaposed relationship.

8. A solar cell module as set forth in claim 1, wherein the at least one upper solar cell and the at least one lower solar cell respectively have at least one photovoltaically active semiconductor layer, the spectral sensitivity of which is different.

9. A solar cell module as set forth in claim 6, wherein the at least two upper solar cells respectively have at least one photovoltaically active semiconductor layer, the spectral sensitivity of which is different.

10. A solar cell module as set forth in claim 1, wherein at least two electrically interconnected lower solar cells are arranged on the underside of the carrier substrate.

11. A solar cell module as set forth in claim 10, wherein the at least two lower solar cells are arranged stacked one upon the other when viewed parallel to the plane of the carrier substrate and/or are arranged in mutually juxtaposed relationship.

12. A solar cell module as set forth in claim 11, wherein the at least two lower solar cells respectively have at least one photovoltaically active semiconductor layer, the spectral sensitivity of which is different.

13. A solar cell module as set forth in claim 1, wherein the at least one upper solar cell and the at least one lower solar cell when viewed perpendicularly to the plane of the carrier substrate are of a different surface extent and/or contour.

14. A solar cell module as set forth in claim 1, wherein the carrier substrate is formed from glass or plastic material, in particular PET, PEN or PVC.

15. A solar cell module as set forth in claim 1, wherein the carrier substrate is of a layer thickness in the range of between 6 μm and 1 mm.

16. A solar cell module as set forth in claim 1, wherein the carrier substrate is transparent or semitransparent.

17. A solar cell module as set forth in claim 1, wherein the at least one upper solar cell and the at least one lower solar cell respectively have at least one translucent electrically conducting first electrode layer, at least one photovoltaically active semiconductor layer and at least one translucent electrically conducting second electrode layer, wherein the at least one photovoltaically active semiconductor layer is arranged between the at least one first electrode layer and the at least one second electrode layer.

18. A solar cell module as set forth in claim 17, wherein the solar cell module and/or the at least one upper solar cell and/or the at least one lower solar cell further has at least one translucent functional layer which increases the efficiency of the respective and/or respective other solar cell.

19. A solar cell module as set forth in claim 17, wherein the at least one photovoltaically active semiconductor layer is an organic semiconductor layer which is formed by at least two organic semiconductor materials by a procedure whereby a composite is formed from at least one electron donor and at least one electron acceptor in a ratio of between 2:0.5 and 0.5:2.

20. A solar cell module as set forth in claim 19, wherein the at least one electron donor is formed from a polythiophene and the at least one electron acceptor is formed from a fullerene derivative.

21. A solar cell module as set forth in claim 1, wherein the solar cell module and/or the at least one upper solar cell and/or the at least one lower solar cell has on the side remote from the carrier substrate a translucent encapsulation layer.

22. A process for the production of a solar cell module as set forth in claim 1, wherein the at least one upper solar cell and the at least one lower solar cell are printed on to the carrier substrate.

23. A process for the production of a solar cell module as set forth in claim 17, wherein at least the at least one photovoltaically active semiconductor layer of the at least one upper solar cell and the at least one lower solar cell are printed.

24. A process as set forth in claim 22, wherein formation of the at least one upper solar cell on the top side of the carrier substrate is effected first and then formation of the at least one lower solar cell on the underside of the carrier substrate is effected.

25. A process as set forth in claim 21, wherein the formation of the at least one upper solar cell on the top side of the carrier substrate and the formation of the at least one lower solar cell on the underside of the carrier substrate are effected simultaneously.

26. A process as set forth in claim 22, wherein the top side and/or the underside of the carrier substrate is provided with at least one position marking and that positioning of the at least one lower or upper solar cell is effected in accurate positional relationship with the at least one upper or lower solar cell by means of alignment of the at least one lower or upper solar cell at the at least one position marking.

27. A process as set forth in claim 26, wherein the at least one position marking is printed on to the substrate.

28. A process as set forth in claim 22, wherein the at least one upper solar cell and the at least one lower solar cell are formed in a roll-to-roll process on the flexible carrier substrate.
